(19) United States
(12) Patent Application Publication
(10) Pub. No.: US 2009/0000943 A1
(43) Pub. Date: Jan. 1, 2009

(54) MAGNETRON SPUTTERING APPARATUS AND MANUFACTURING METHOD FOR STRUCTURE OF THIN FILM

(75) Inventors: Atsushi FURUYA, Kawasaki (JP); Akihiko FUJISAKI, Kawasaki (JP); Tetsuyuki KUBOTA, Kawasaki (JP); Tomoko KUTSUZAWA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/144,301

(22) Filed: Jun. 23, 2008

(30) Foreign Application Priority Data
Jun. 28, 2007 (JP) 2007-170587

(51) Int. Cl. C23C 14/35

(52) U.S. Cl. 204/192.12; 204/298.16

(57) ABSTRACT

According to an aspect of an embodiment, a magnetron sputtering apparatus sputtering a target by a plasma includes a plurality of magnets that are arranged in the vicinity of a position where the target is disposed. The plurality of magnets form a magnetic field for confining the plasma; and a rotating mechanism rotates the plurality of magnets around a rotation center.

### CROSS-REFERENCE TO RELATED APPLICATIONS

This application is based upon and claims the benefit of priority from the prior Japanese Patent Application No. 2007-170587 filed on Jun. 28, 2007, the entire contents of which are incorporated herein by reference.

### FIELD

An aspect of the invention relates to a magnetron sputtering apparatus and, more particularly, to a magnetron sputtering apparatus that forms a magnetic field on a target and performs sputtering while confining a plasma and a manufacturing method for the structure of a thin film performed by using the magnetron sputtering apparatus.

### BACKGROUND

A magnetron sputtering apparatus is used in the semiconductor fabrication industry to form a film of various materials (for example, aluminum) on a substrate such as a silicon wafer during integrated circuit manufacturing. The magnetron sputtering apparatus is a film forming apparatus that generates a plasma near a target, such as a film forming material. The magnetron sputtering apparatus sputters the target by causing ion atoms generated from the plasma to collide against the target at a high velocity, forming a thin film of the target material on the wafer.

FIG. 1 is a schematic diagram of sputtering in a magnetron sputtering apparatus. Lines of magnetic force of a magnetic field are formed by a pair of permanent magnets 102A, 102B. Electrons emitted from a target 100 are confined in positions where the lines of magnetic force are parallel to the surface of the target. As a result of this, a plasma 104 is formed around a position where a line of magnetic force becomes parallel near the target 100. The collision of ions of this plasma 104 against the target 100 causes the target 100 to be sputtered. The sputtered particles 106 scatter and are deposited on a wafer 108, forming a thin film 110 of the target material on the wafer 108.

Because the plasma on the target 100 moves in a direction orthogonal to the lines of magnetic force, as shown in FIG. 2, it is necessary to form a line of magnetic force so that a loop which is closed in the moving direction of the plasma is formed in order to confine the plasma on the target 100. For this purpose, lines of magnetic force are formed on the lower side of the target 100, as shown in FIG. 2, by disposing a plurality of pairs of magnets so as to form a loop.

When a plasma is generated along a loop as described above, only the part of the target to be sputtered extends along the loop, and only this part is sputtered and attacked. This attack is called erosion. When erosion occurs locally, the thickness of the target is reduced at that point. Consequently, the target must be replaced before the target is perforated with holes. Therefore, the following references describe rotating the plasma loop itself after the loop is deformed so as not to be annular in order to ensure that erosion occurs as evenly a possible on the whole target.

[Patent Document 1]

Japanese Laid-open Patent Publication No. 2003-531284

[Patent Document 2]

Japanese Laid-open Patent Publication No. 9-195042

[Patent Document 3]

Japanese Laid-open Patent Publication No. 3-6371

[Patent Document 4]

Japanese Laid-open Patent Publication No. 9-95781

Since, as described above, the plasma loop is determined by the arrangement and configuration of permanent magnets, it is possible to ensure that erosion occurs as evenly as possible on the whole target by devising the arrangement and configuration of permanent magnets.

Although a variety of patterns are conceivable as arrangement and configuration of permanent magnets, an optimum pattern has not been determined as yet and it is necessary to find out a pattern that enables a target to be used more efficiently (i.e., for a longer time). Particularly, in recent years the prices of materials for targets have risen sharply and it has become increasingly necessary to use one target for a longer time.

### SUMMARY

The present patent application has been filed in view of the above-described problems. An aspect of the invention is to provide a magnetron sputtering apparatus capable of reducing the consumption of targets by ensuring efficient consumption of the targets.

According to an aspect of an embodiment, a magnetron sputtering apparatus sputtering a target by a plasma includes a plurality of magnets that are arranged in the vicinity of a position where the target is disposed and form a magnetic field for confining the plasma; and a rotating mechanism that rotates the plurality of magnets around a rotation center, wherein the plurality of magnets are arranged in such a manner as to form a magnetic field straddling the closed curve in the vicinity of a surface of the target, wherein the rotation center is within a region enclosed by the closed curve. The closed curve has a plurality of convexities and a plurality of concavities wherein the distance between each of the convexities and the rotation center is different from each other and the distance between each of the concavities and the rotation center is different from each other.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a conceptual diagram showing sputtering in a magnetron sputtering apparatus;

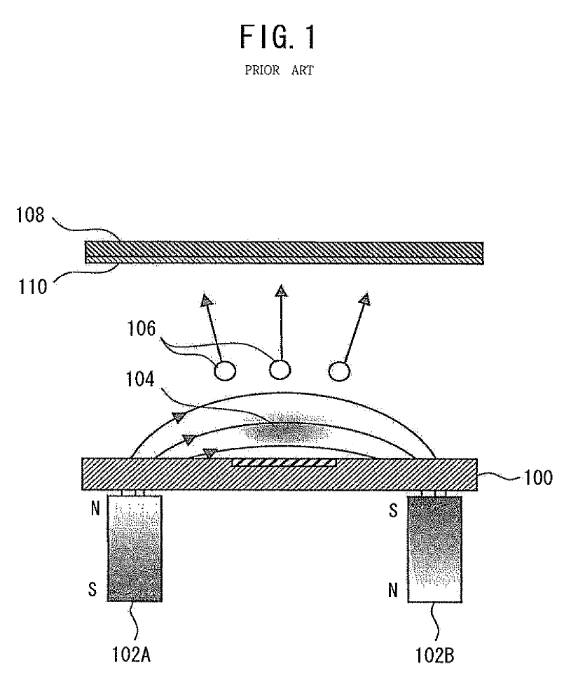

FIG. 2 is a perspective view showing the position of a plasma generated on a target;

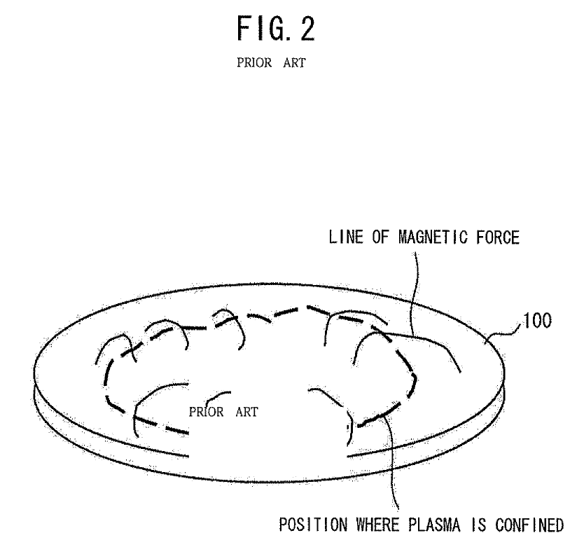

FIG. 3 is a schematic diagram showing an outline of a magnetron sputtering apparatus to which an aspect of the invention is applied;

FIG. 4 is an enlarged sectional view of a magnetron cathode shown in FIG. 3;

FIG. 5 is a graph showing the ion collision density near the surface of a target;

FIG. 6 is a plan view showing an arrangement pattern of permanent magnets in an embodiment of an aspect of the invention;

FIG. 7 is a diagram showing a curve corresponding to the horizontal positions of a magnetic field generated by the arrangement pattern of permanent magnets in FIG. 6;

FIG. 8 is a graph showing the distance to the horizontal positions of a magnetic field in the plane of a target as viewed from the rotation center P;

FIG. 9 is a graph showing the distribution of the length of a curve in the horizontal positions of a magnetic field as viewed from the rotation center P;

FIG. 10 is a graph showing the erosion profile of a target obtained when sputtering was performed by using the magnet arrangement shown in FIG. 6;

FIG. 11 is a diagram showing a closed curve formed by connecting the horizontal positions of a magnetic field when the closed curve has four convexities and four concavities;

FIG. 12 is a graph showing the erosion profile of a target obtained by arranging magnets so that the closed curve shown in FIG. 11 is formed;

FIG. 13 is a diagram showing a closed curve formed by connecting the horizontal positions of a magnetic field when the closed curve has two convexities and two concavities; and

FIG. 14 is a graph showing the erosion profile of a target obtained by arranging magnets so that the closed curve shown in FIG. 13 is formed.

### DETAILED DESCRIPTION OF THE PREFERRED EMBODIMENTS

Reference may now be made in detail to embodiments of the present invention, examples of which are illustrated in the accompanying drawings, wherein like reference numerals refer to like elements throughout.

An embodiment will be described with reference to the drawings.

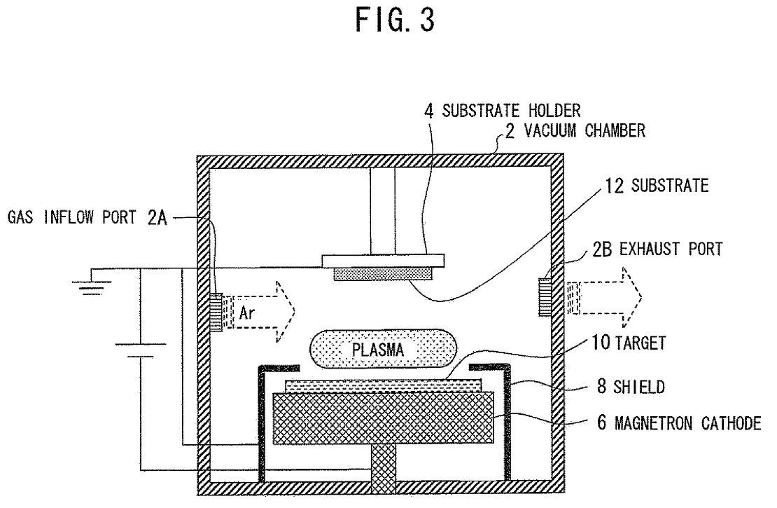

First, a magnetron sputtering apparatus to which an aspect of the invention is applied will be described with reference to FIG. 3.

The magnetron sputtering apparatus shown in FIG. 3 has a vacuum chamber 2. The vacuum chamber 2 is a hermetically sealed vessel whose interior can be maintained in a condition close to a vacuum. The vacuum chamber 2 is provided with a gas inflow port 2A and an exhaust port 2B. A gas (for example, Argon (Ar) gas) is supplied from the gas inflow port 2A to the interior of the vacuum chamber 2 as a plasma source. The gas in the vacuum chamber 2 is exhausted from the exhaust port 2B and the interior of the vacuum chamber 2 is maintained at a prescribed degree of vacuum.

A substrate holder 4 and a magnetron cathode 6 are provided within the vacuum chamber 2. The surrounding area of the magnetron cathode 6 is covered with a shield 8. A target 10, which is a film making material, is placed on the magnetron cathode 6. A substrate 12, which is an object of film formation, is attached to a substrate holder 4 so as to be opposed to the target 10.

The substrate holder 4 and the shield 8 within the vacuum chamber 2 are grounded. The substrate holder 4 acts as an anode. A voltage of several hundreds of volts is applied to the magnetron cathode 6 from a power supply. In a usual magnetron sputtering apparatus, Ar and the like, which are inactive gases, are used as a plasma gas. The plasma gas is supplied from the gas inflow port 2A into the interior of the vacuum chamber 2. A magnet unit 16, which is also called a magnetic field generating unit, is built in the magnetron cathode 6.

The magnet unit generates a leakage magnetic field near the surface of the target 10 so that a plasma is confined near the target 10. When a voltage is applied to the magnetron cathode 6, electrons are confined by the leakage magnetic field near the surface of the target 10, and the collision of the electrons against Ar atoms generates Ar ions. Ionized Ar+ is accelerated by a sheath electric field generated between the plasma and the target 10, whereby sputtering occurs.

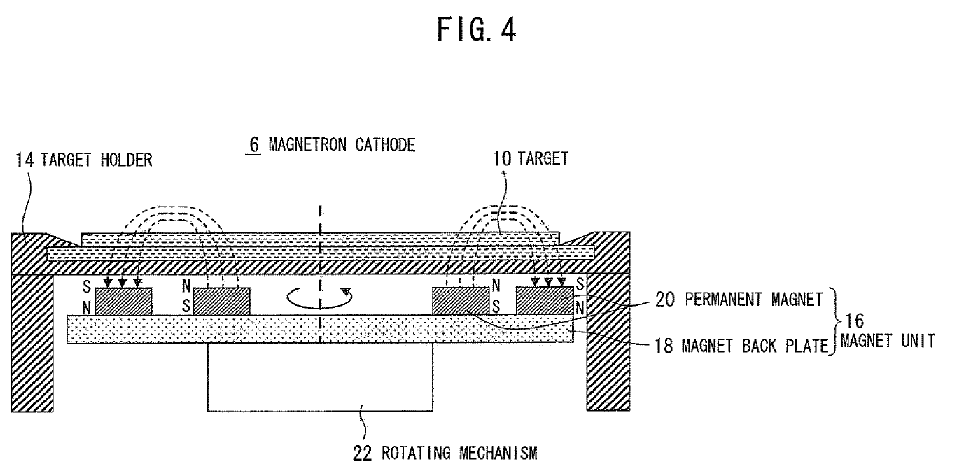

FIG. 4 is an enlarged sectional view of the magnetron cathode 6 shown in FIG. 3. A target holder 14 is provided in a top portion of the magnetron cathode 6. The target 10 is placed on the target holder 14 and supported thereon. The above-described magnet unit 16 is provided below the target holder 14.

The magnet unit 16, which is a magnetic field generating unit, has a disk-shaped magnet back plate 18 and a plurality of permanent magnets 20 fixed onto the magnet back plate 18. The plurality of permanent magnets 20 are arranged in a prescribed pattern, as will be described later. The plurality of permanent magnets 20 generate a magnetic field for confining the plasma near the surface of the target 10. The magnet unit 16 is attached to a rotating mechanism 22. The rotating mechanism 22 can rotate the magnet unit 16 below the target 10 by driving the rotating mechanism 22. As a result of this, it is possible to rotate the magnetic field generated near the surface of the target 10 within a plane parallel to the surface of the target 10. The rotating mechanism 22 is a commonly-known mechanism that rotates the magnet back plate 18 by the power of an electrically-driven motor, and hence its description is omitted.

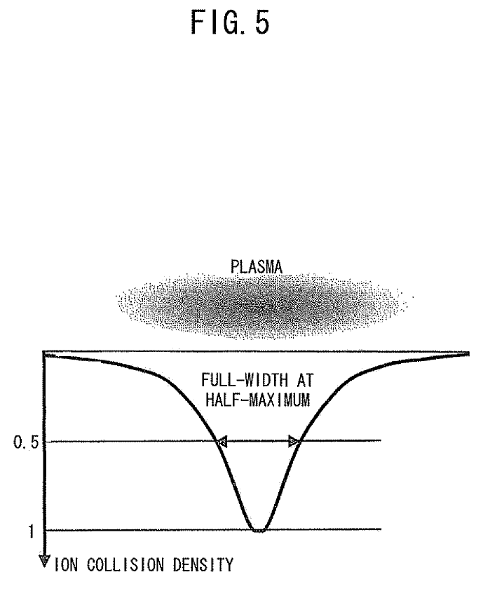

The plasma generated near the surface of the target 10 is confined within a region having a width corresponding to the magnetic field for plasma confinement. The width of this region is called the plasma confinement width. The plasma confinement width is explained here with reference to FIG. 5. FIG. 5 is a graph showing the ion collision density near the surface of the target.

Because it is difficult to actually measure plasma density, plasma density is estimated by measuring the collision density of ions in the plasma or the sputtering rate. The density of the plasma confined in a magnetic field becomes a curve close to a Gaussian distribution as shown in FIG. 5. The plasma confinement width is usually defined as a full-width at half-maximum, which is a width obtained when the ion collision density becomes half a peak value. In a general magnetron sputtering apparatus, this full-width at half-maximum is approximately 6 mm. Therefore, a strip-shaped plasma having a full-width at half-maximum of approximately 6 mm is generated near the surface of the target. Because the strip-shaped plasma moves in a direction perpendicular to the line of magnetic force of a magnetic field, it is necessary to form a magnetic field so that the strip-shaped plasma forms a loop (or a closed curve) on the surface of the target.

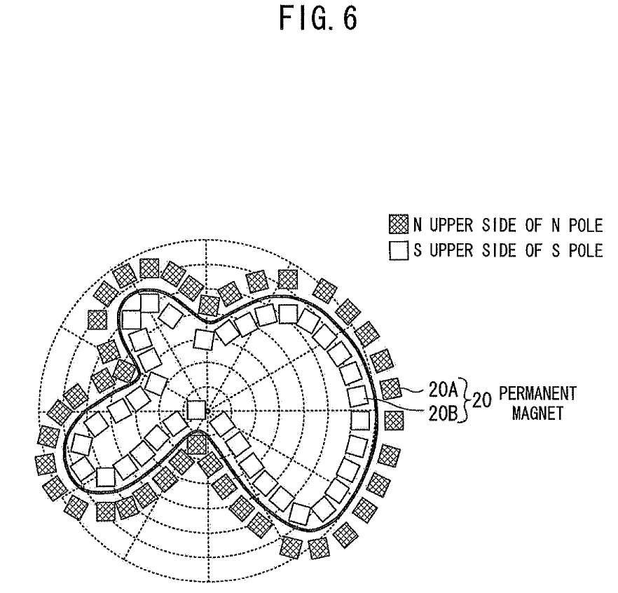

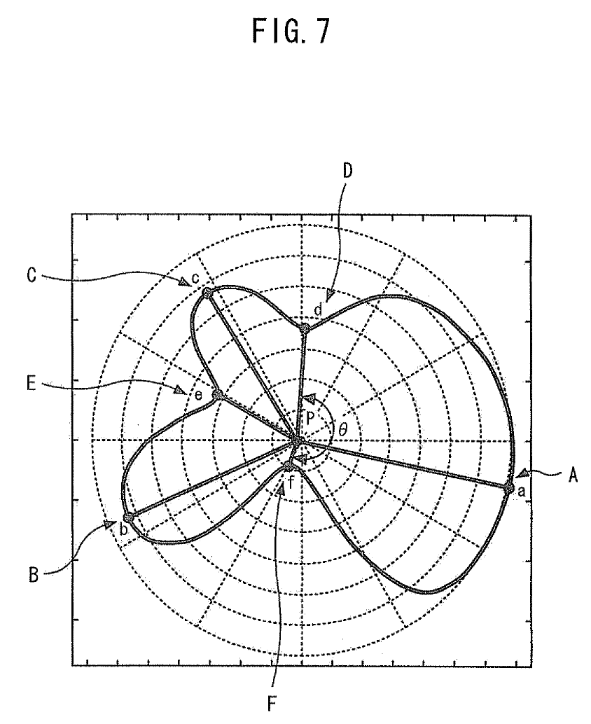

Next, a description will be given of the arrangement pattern of the permanent magnets 20 that form a magnetic field for plasma confinement in a magnetron sputtering apparatus according to an embodiment. FIG. 6 is a plan view showing an arrangement pattern of the permanent magnets 20 according to an embodiment, and FIG. 7 is a diagram showing a curve corresponding to horizontal positions of a magnetic field on the surface of the target generated by the arrangement pattern of the magnets in FIG. 6.

As shown in FIG. 6, the permanent magnets 20 that generate a magnetic field for plasma confinement include a plurality of pairs of magnets 20A, 20B. The magnets 20A, 20B, which constitute a pair, are arranged so that the upper part of the magnet 20A becomes an S pole and the upper part of the magnet 20B becomes an N pole (see FIG. 4), to ensure that a magnetic field is generated between the magnets 20A and 20B. When the target 10 is arranged near the magnets 20A, 20B, a line of magnetic force moving from the magnet 20A, which acts as the S pole, to the magnet 20B, which acts as the N pole, extends upward from the magnet 20A. The line of magnetic force then pierces through the target 10, turns back and is bent back near the surface of the target, pierces again downward through the target 10, and reaches the magnet 20B.

A portion of the line of magnetic force where the line of magnetic force becomes parallel to the surface of the target 10 is formed where the line of magnetic force turns back near the surface of the target 10. The plasma is confined in this portion where the line of magnetic force becomes parallel to the surface of the target 10. The position of the portion of the line of magnetic force where the line of magnetic force becomes parallel to the surface of the target 10 is called a horizontal position of a magnetic field. Therefore, a horizontal position of a magnetic field is substantially in the middle of the magnets 20A, 20B that constitute a pair. The closed curve shown in FIG. 7 is a curve formed by connecting the horizontal positions of a magnetic field, and provides a shape determined by the arrangement pattern of the magnets 20A, 20B.

In this embodiment, as shown in FIG. 7, the closed curve formed by connecting the horizontal positions of a magnetic field is a deformed loop-like curve having three convexities and three concavities. In other words, in this embodiment, the magnets 20A, 20B are arranged so that the pattern formed by connecting the horizontal positions of a magnetic field becomes a closed curve having three convexities and three concavities. The plasma is confined in the shape of a strip along this closed curve. Incidentally, the number of convexities and the number of concavities is not limited to three. The number of convexities and the number of concavities may be two or four as will be described later.

When the rotating mechanism 22 is driven and the magnet unit 16 is rotated, the magnets 20A, 20B rotate around the rotation center in a plane parallel to the surface of the target 10. Therefore, a closed curve formed by connecting the horizontal positions of a magnetic field rotates around the rotation center on the surface of the target 10. As a result of this, the plasma confined along the closed curve rotates and moves on the surface of the target 10. Therefore, the position of the erosion of the target by the plasma rotates and moves and the whole surface of the target 10 is substantially uniformly sputtered.

In this embodiment, by devising the shape of the closed curve formed by connecting the horizontal positions of a magnetic field shown in FIG. 7, it is ensured that the whole surface of the target 10 is sputtered as uniformly as possible. As shown in FIG. 7, in this embodiment, the closed curve formed by connecting the horizontal positions of a magnetic field has three convexities A, B, C and three concavities D, E, F formed between the convexities A, B, C. Moreover, the above-described rotation center P is within a region enclosed by the closed curve. In other words, the magnets 20A, 20B are arranged so that the line that connects substantially the middle of the magnets 20A, 20B that constitute a pair, becomes a closed curve including the rotating shaft of the magnet unit 16.

If the apexes of the convexities A, B, C (positions most distant from the rotation center P) denote a, b, c, respectively, then the distance from the rotation center P to the apex a of the convexity A, the distance from the rotation center P to the apex b of the convexity B, and the distance from the rotation center P to the apex c of the convexity C are different from each other. Similarly, if the valley bottoms of the concavities D, E, F (positions closest to the rotation center P) denote d, e, f, respectively, then the distance from the rotation center P to the valley bottom d of the concavity D, the distance from the rotation center P to the valley bottom e of the concavity E, and the distance from the rotation center P to the valley bottom f of the concavity F are different from each other.

It is preferred that the central angle of the largest convexity (the convexity in which the distance to the apex is most distant from the rotation center P) be larger than the central angle of all other convexities. The central angle of a convexity can be defined as an angle formed by lines connecting the valley bottom of the convexities present on the right and left sides of this convexity and the rotation center. In this embodiment, as shown in FIG. 7, the largest convexity is the convexity A, and the central angle of the convexity A is the angle θ formed by connecting the right and left convexities D and F and the rotation center P. Furthermore, the central angle for the smallest convexity C is the smallest angle formed by connecting the right and left concavities D and E and the rotation center P, and agreement exists between the magnitude correlation of the convexities and the magnitude correlation of the central angle corresponding to the convexities.

Furthermore, it is preferred that the distance between the apexes a, b, c of the convexities A, B, C and the rotation center P be different from each other by not less than half the above-described full-width at half-maximum of the plasma. Similarly, it is preferred that the distance between the valley bottoms d, e, f of the concavities D, E, F and the rotation center P be different from each other by not less than half the above-described full-width at half-maximum of the plasma. Usually, the full-width at half-maximum of the plasma is 6 mm and hence it is preferred that the difference in the distance be not less than 3 mm.

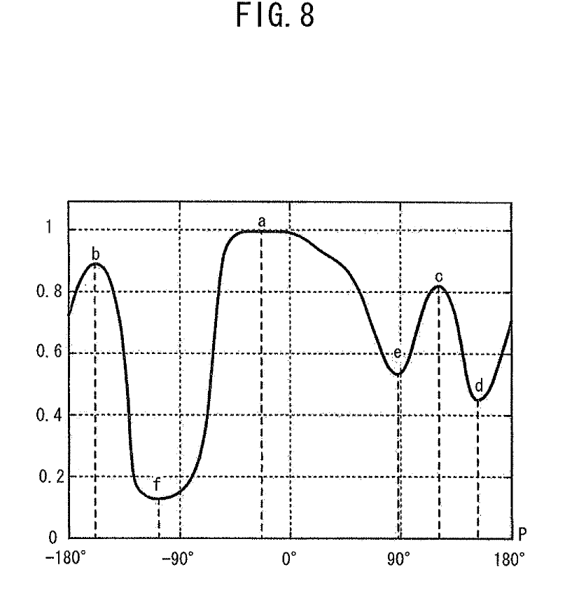

FIG. 8 is a graph showing the distance to the horizontal positions of a magnetic field in the plane of the target 10 as viewed from the rotation center P. In FIG. 8, the abscissa indicates the angular position, and angular positions from −180 degrees to +180 degrees for one circumference are indicated. The ordinate indicates the distance from the rotation center P to each point of the curve. It is apparent that the distance from the rotation center P to each of the points a, b, c, d, e, f is different from each other. Incidentally, on the ordinate is plotted the ratio in a case where the distance to the most distant point from the rotation center P, i.e., the apex a of the convexity A is 1.

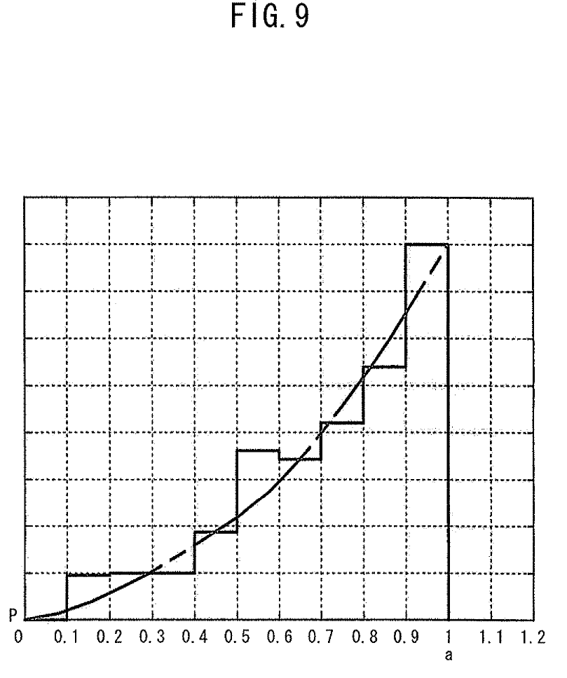

FIG. 9 is a graph showing the distribution of the length of a curve in the horizontal positions of a magnetic field as viewed from the rotation center P. The abscissa of FIG. 9 indicates the distance from the rotation center P, and the ordinate indicates the length of the horizontal positions of a magnetic field. It is apparent from the graph of FIG. 9 that the length in the horizontal positions of a magnetic field increases almost in proportion to the distance from the rotation center P. That is, the larger the distance (radius of rotation) from the rotation center P at a point, the larger the distance (circumference) over which the point moves in one rotation, and the erosion of the target 10 decreases by just that much. Therefore, by increasing the distance over which the point moves on the target per unit time (distance on the circumference), it is ensured that erosion proceeds uniformly regardless of the distance from the rotation center P.

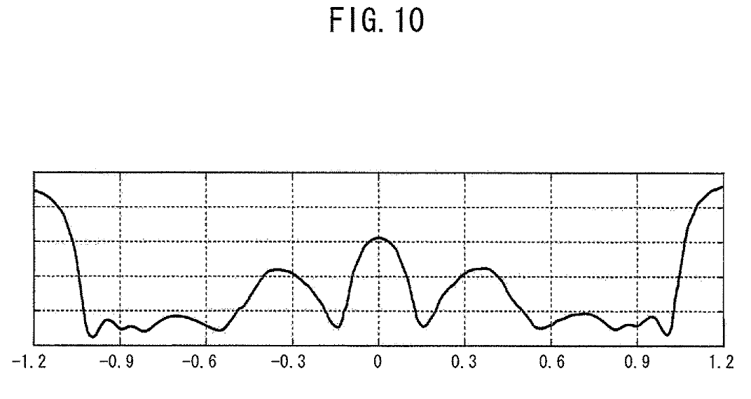

FIG. 10 is a graph showing the erosion profile of the target 10 obtained when sputtering was performed by using the magnet arrangement shown in FIG. 6. In the graph shown in FIG. 10, the abscissa indicates radial positions of the target 10, and the ordinate indicates the height of the surface of the target 10 removed by the erosion (i.e., the depth of the removed part). As is apparent from FIG. 10, the erosion proceeds almost uniformly on the whole surface of the target 10.

As described above, by using the magnet arrangement according to this embodiment, the whole surface of the target 10 is substantially uniformly eroded and the target 10 is not locally removed. Thus, it is possible to raise the utilization efficiency of the target 10. As a result of this, expensive target materials can be used without waste, and the cost of film formation can be reduced. Because the whole surface of the target 10 is uniformly sputtered, the emission angle of sputtered particles is kept constant. Therefore, it is possible to suppress changes in the film forming conditions ascribed to changes in the emission angle of sputtered particles. Because of this, a film formed by sputtering can be made homogeneous and the film thickness can be made uniform.

Although in the above-described embodiment the closed curve formed by connecting the horizontal positions of a magnetic field has three convexities and three concavities, the same effect as in the above-described embodiment can be obtained also when the number of convexities and the number of concavities are each two or four.

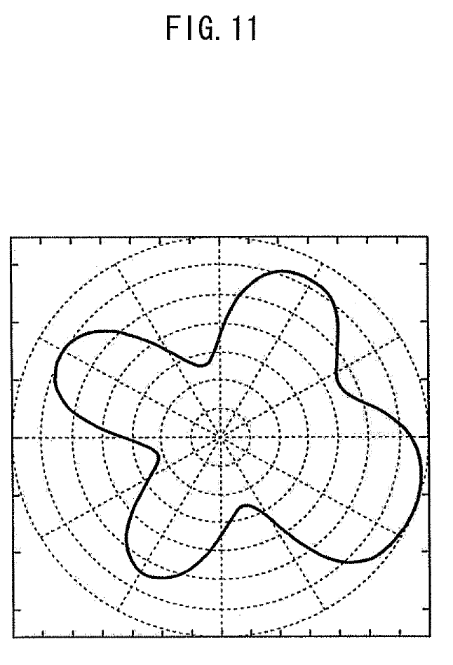

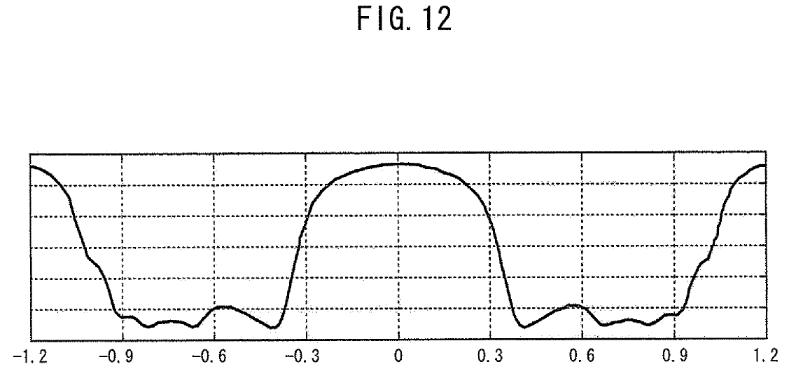

FIG. 11 is a diagram showing a closed curve formed by connecting the horizontal positions of a magnetic field when the closed curve has four convexities and four concavities. Also in the closed curve shown in FIG. 11, the rotation center is within a region enclosed by the closed curve, the distance from the rotation center to the apex of each of the convexities is different from each other, and also the distance from the rotation center to the valley bottom of each of the concavities is different from each other. FIG. 12 is a graph showing the erosion profile of the target 10 obtained by arranging magnets so that such a closed curve is formed. Compared to the erosion profile shown in FIG. 10, the erosion of the middle part is small. However, the area of the middle part is small in the whole area, and the utilization efficiency of the target is only a little low compared to the case of the erosion profile shown in FIG. 10.

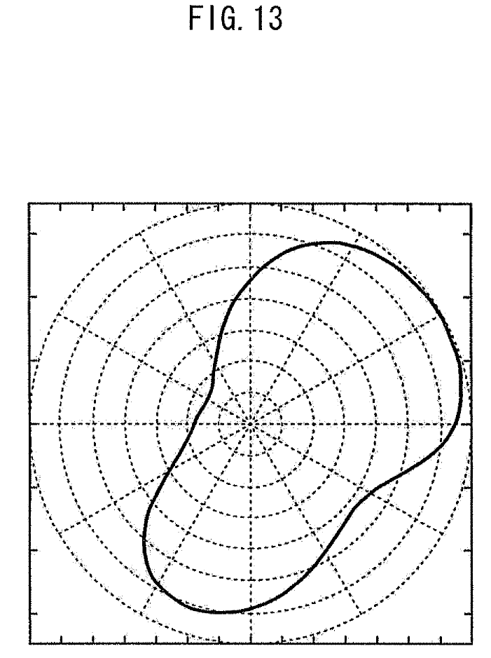

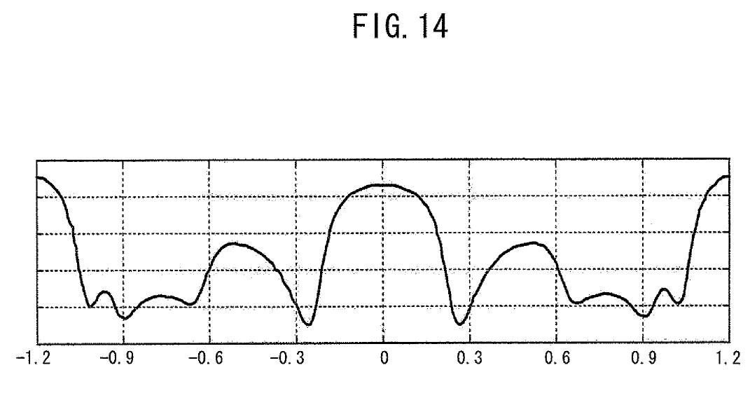

FIG. 13 is a diagram showing a closed curve formed by connecting the horizontal positions of a magnetic field when the closed curve has two convexities and two concavities. Also in the closed curve shown in FIG. 13, the rotation center is within a region enclosed by the closed curve, the distance from the rotation center to the apex of each of the convexities is different from each other, and also the distance from the rotation center to the valley bottom of each of the concavities is different from each other. FIG. 14 is a graph showing the erosion profile of the target 10 obtained by arranging magnets so that such a closed curve is formed. Compared to the erosion profile shown in FIG. 10, the erosion depth of the middle part has large concavities and convexities. However, the utilization efficiency of the target is only a little low compared to the case of the erosion profile shown in FIG. 10.

According to the above-described an aspect of the invention, the target is uniformly eroded throughout the surface and it is possible to raise the utilization efficiency of the target. As a result of this, expensive target materials can be used without waste and the cost of film formation can be reduced.

Furthermore, uniformly sputtering the whole surface of the target enables the emission angle of sputtered particles to be kept constant and hence it is possible to suppress changes in the film forming conditions ascribed to changes in the emission angle of sputtered particles.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A magnetron sputtering apparatus sputtering a target by a plasma comprising:
a plurality of magnets that are arranged in the vicinity of the target and form a magnetic field for confining the plasma; and
a rotating mechanism that rotates the plurality of magnets around a rotation center,
wherein the plurality of magnets form a magnetic field straddling a closed curve in the vicinity of a surface of the target,
wherein the rotation center is within a region enclosed by the closed curve, and
wherein the closed curve has a plurality of convexities and a plurality of concavities, a distance between each of the convexities and the rotation center being different from each other and a distance between each of the concavities and the rotation center being different from each other.

2. The magnetron sputtering apparatus according to claim 1, wherein an apex of a convexity having a largest central angle of all the convexities is most distant from the rotation center.

3. The magnetron sputtering apparatus according to claim 1, wherein both the distance between each of the convexities and the rotation center and the distance between each of the concavities and the rotation center are different from each other by at least half a confinement width of the plasma.

4. The magnetron sputtering apparatus according to claim 1, wherein the distance of a valley bottom of a concavity closest to the rotation center of all the concavities from the rotation center is not less than half a confinement width of the plasma.

5. The magnetron sputtering apparatus according to claim 3, wherein the confinement width is approximately 6 mm.

6. The magnetron sputtering apparatus according to claim 1, wherein the closed curve has the convexities in quantities of two to four and the concavities in quantities of two to four.

7. A magnetron sputtering apparatus sputtering a target by a plasma comprising:
a target to be sputtered;
a magnetic field generating unit in which magnets are arranged along a closed curve on a plane approaching the target, which generates a magnetic field on a surface of the target and confines a plasma within the magnetic field; and
a rotating mechanism that rotates the target and the magnetic field generating unit around a point inside the curve as a center,
wherein the closed curve has a plurality of convexities and a plurality of concavities, and
wherein a distance between each of the convexities of the curve and the rotation center is different from each other and a distance between each of the concavities of the curve and the rotation center is different from each other.

8. The magnetron sputtering apparatus according to claim 7, wherein an apex of a convexity having a largest central angle of all the convexities is most distant from the rotation center.

9. The magnetron sputtering apparatus according to claim 7, wherein both the distance between each of the convexities and the rotation center and the distance between each of the concavities and the rotation center are different from each other by at least half a confinement width of the plasma.

10. The magnetron sputtering apparatus according to claim 7, wherein the distance of a valley bottom of a concavity closest to the rotation center of all the concavities from the rotation center is not less than half a confinement width of the plasma.

11. The magnetron sputtering apparatus according to claim 9, wherein the confinement width is approximately 6 mm.

12. The magnetron sputtering apparatus according to claim 7, wherein the closed curve has the convexities in quantities of two to four and the concavities in quantities of two to four.

13. A manufacturing method for a structure of a thin film comprising:
rotating a magnetic field generating unit and a target to be sputtered around a rotation center, the magnetic field generating unit being configured in such a manner that a plurality of magnets are arranged along a closed curve so as to enclose the rotation center on a plane approaching the target, the distance between each of a plurality of convexities of the closed curve and the rotation center is different from each other and the distance between each of a plurality of concavities of the closed curve and the rotation center is different from each other; and
confining a plasma on the target along the closed curve by using a magnetic field generated by the magnetic field generating unit, and sputtering the target by using the plasma thereby to form a thin film.
